(19) United States
(12) Patent Application Publication
(10) Pub. No.: US 2024/0297092 A1
(43) Pub. Date: Sep. 5, 2024

(54) PACKAGE STRUCTURE OF CHIP AND INTEGRATED HEAT SPREADER

(71) Applicant: Acer Incorporated, New Taipei City (TW)

(72) Inventors: Kuang-Hua Lin, New Taipei City (TW); Cheng-Wen Hsieh, New Taipei City (TW); Mao-Neng Liao, New Taipei City (TW); Wen-Chieh Tai, New Taipei City (TW)

(73) Assignee: Acer Incorporated, New Taipei City (TW)

(21) Appl. No.: 18/582,671

(22) Filed: Feb. 21, 2024

(30) Foreign Application Priority Data
Mar. 1, 2023 (TW) 112107361

(51) Int. Cl. H01L 23/373; H01L 23/367

(52) U.S. Cl. CPC H01L 23/3735; H01L 23/3675

(57) ABSTRACT

A package structure of chip and integrated heat spreader including a substrate, a chip disposed on the substrate, a thermal interface material disposed on the chip, and an integrated heat spreader disposed on the substrate is provided. The integrated heat spreader is a lid covering the chip and the thermal interface material, and the thermal interface material is abutted between the chip and the integrated heat spreader. The integrated heat spreader is composed of a graphite plate and at least one copper layer, wherein an exterior surface of the graphite plate is totally covered by the copper layer.

### CROSS-REFERENCE TO RELATED APPLICATION

This application claims the priority benefit of Taiwan application serial no. 112107361, filed on Mar. 1, 2023. The entirety of each of the above-mentioned patent applications is hereby incorporated by reference herein and made a part of this specification.

### BACKGROUND

### Technical Field

The disclosure relates to a packaging structure for a chip and an integrated heat spreader.

### Description of Related Art

Electronic components such as semiconductors, integrated circuit packaging, and transistors typically have an optimal operating temperature. However, if the heat generated by electronic components during operation is not removed, the electronic components will operate in a significantly high-temperature environment, which is detrimental to the operating characteristics of the electronic components and the operation of associated devices.

Especially with the advancement of semiconductor technology, there are often electronic components and integrated circuits with higher densities. Therefore, semiconductor chips generate more heat when they are in operation.

Therefore, providing corresponding heat dissipation means for electronic components and integrated circuits with higher densities is a problem that needs to be considered and solved by relevant technical personnel.

### SUMMARY

The present invention provides a packaging structure for a chip and an integrated heat spreader that can provide a heat dissipation path with better thermal efficiency by combining a graphite plate with a heat transfer medium.

The packaging structure for the chip and integrated heat spreader of the present invention includes a substrate, a chip, a thermal interface material, and an integrated heat spreader. The chip is disposed on the substrate, and the thermal interface material is disposed on the chip. The integrated heat spreader is in a lid shape, disposed on the substrate to cover the chip and the thermal interface material, wherein the thermal interface material is abutted between the chip and the integrated heat spreader. The integrated heat spreader is composed of a graphite plate and at least one copper layer, wherein an exterior surface of the graphite plate is totally covered by the copper layer.

Based on the above, the integrated heat spreader of the embodiment is based on the graphite plate and completely covered with the copper layer on its outer surface to form the required integrated heat spreader, which can effectively transmit the heat generated by the chip to the integrated heat spreader quickly via the thermal interface material, and dissipate the heat from the integrated heat spreader.

### BRIEF DESCRIPTION OF THE DRAWINGS

FIG. 1 is a simplified cross-sectional view of a package structure according to an embodiment of the invention.

FIG. 2 is a schematic diagram of components of the heat spreader in FIG. 1.

FIG. 3 is a partial cross-sectional view of a package structure according to another embodiment of the present invention.

### DESCRIPTION OF THE EMBODIMENTS

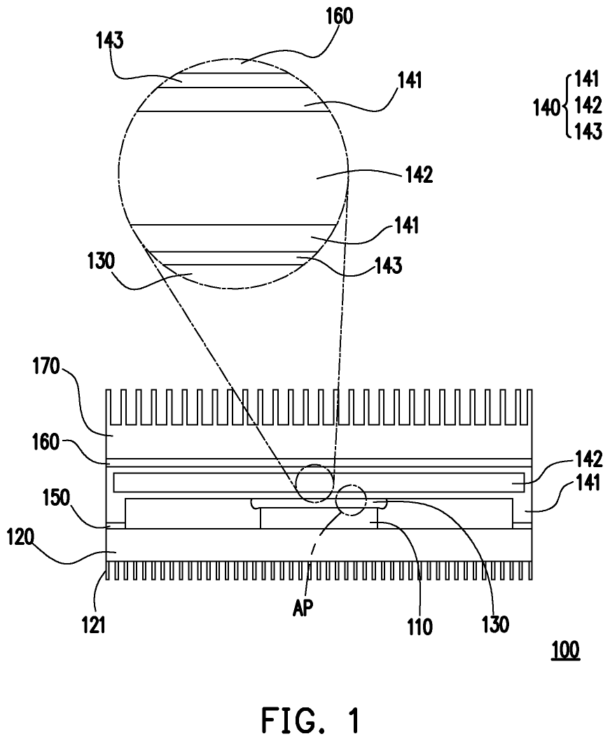

FIG. 1 is a simplified cross-sectional view of a package structure according to an embodiment of the invention. Referring to FIG. 1, in the embodiment, the package structure 100, that is, the package structure of the chip and the integrated heat sink, such as a central processor, which includes a substrate 120, a chip 110, a thermal interface material 130 and an integrated heat spreader 140. The chip 110, such as a bare die, is disposed on the substrate 120 (such as a circuit board), and the thermal interface material 130 is disposed on the chip 110. The integrated heat spreader 140 is in a lid shape and is disposed on the substrate 120 by an adhesive material 150 to cover the chip 110 and the thermal interface material 130, wherein the thermal interface material 130 is abutted between the chip 110 and the integrated heat spreader 140. Here, the package structure 100 is used to provide protection and heat dissipation for the bare die (the chip 110).

Furthermore, the package structure 100 shown in FIG. 1 also includes: the substrate 120 has connecting pins 121 extending away from the chip 110; a heat dissipation fin 170 is disposed on the integrated heat spreader 140 through another thermal interface material 160 and faces away from the integrated heat spreader 140. In this way, after the heat generated by the chip 110 is transmitted to the integrated heat spreader 140, the package structure 100 can be further dissipated through another thermal interface material 160 and the heat dissipation fin 170.

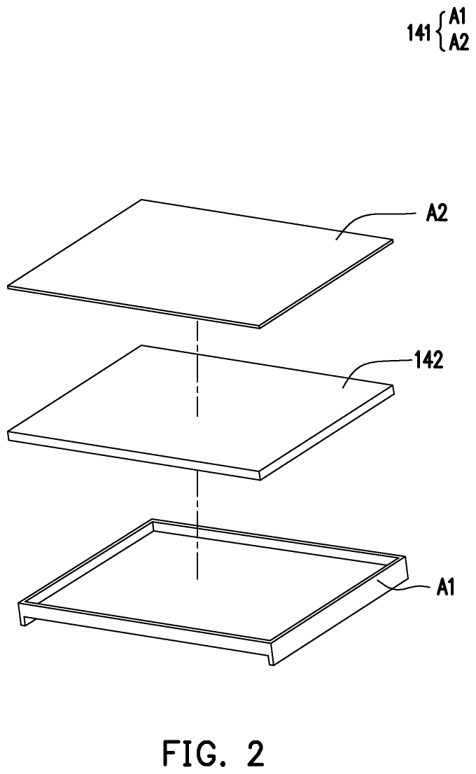

FIG. 2 is a schematic diagram of components of the heat spreader in FIG. 1. Referring to FIG. 1 and FIG. 2 at the same time, in the embodiment, the integrated heat spreader 140 is composed of a graphite plate 142 and at least one copper layer 141, wherein an exterior surface of the graphite plate 142 is totally covered by the copper layer 141. As shown in FIG. 2, the at least one copper layer 141 includes components A1 and A2, which form a space enough to accommodate the graphite plate 142 after being combined with each other. Here, the composite thin-layer heat conduction structure formed by the graphite plate 142 and the copper layer 141, in addition to utilizing the high thermal conductivity (heat transfer coefficient K=1500 W/m·K) of the graphite plate 142, can also provide protection by the copper layer 141 coated on its exterior surface. At the same time, due to the ductility of the copper layer 141, the integrated heat spreader 140 can easily accept post-processing and assembly processes, and prevent the graphite plate 142 from being easily damaged by external forces. Here, the thickness of the graphite plate 142 is 0.7 mm to 3 mm.

Referring to FIG. 1 again, in view of the fact that the copper layer 141 of the integrated heat spreader 140 is susceptible to corrosion due to the influence of ambient temperature, humidity and surrounding components, the integrated heat spreader 140 of the embodiment further includes a nickel layer 143. The nickel layer 143 is plated on an exterior surface of the copper layer 141 and is located on the side facing away from the graphite plate 142. That is, one side of the copper layer 141 can be in contact with the another thermal interface material 160 through the nickel layer 143, and the other side can be in contact with the thermal interface material 130 through the nickel layer 143. Here, the sum of the thicknesses of the copper layer 141 and the nickel layer 143 on one side is 0.05 mm to 2 mm.

Referring to FIG. 1 again, in the embodiment, the thermal interface material 130 used to abut between the chip 110 and the integrated heat spreader 140 can be, for example, liquid metal, which is a low-melting-point alloy that is liquid at room temperature, or an alloy that is in the form of a solid sheet and becomes liquid when heated to the melting point. The components are, for example, gallium-indium-tin alloy, indium-bismuth-tin alloy, or indium-bismuth-zinc alloy, etc., which are stable in nature and have excellent thermal conductivity (heat transfer coefficient 30-40 W/m K) and electrical conductivity. Because it is liquid at normal temperature, it has the convenience of operation. In other words, after at least one of the integrated heat spreader 140 and the chip 110 is coated with the thermal interface material 130, the thermal interface material 130 can be smoothly covered and pressed. In this way, it spreads smoothly in the space between the integrated heat spreader 140 and the chip 110. Here, the thickness of the thermal interface material 130 is 0.1 mm to 0.2 mm. It should be noted that, as a heat transfer medium between the chip 110 and the integrated heat spreader 140, the main purpose of the thermal interface material 130 is to fill a gap between the chip 110 and the integrated heat spreader 140. The gap is due to the difference in surface properties such as roughness and flatness caused by the manufacturing process or materials of the chip 110 and the integrated heat spreader 140. Therefore, in actual operation, the thermal interface material 130 with the thickness of 0.1 mm to 0.2 mm is arranged between the chip 110 and the integrated heat spreader 140. Then, when the three are stacked, the thermal interface material 130 is extruded, so that the thickness of the thermal interface material 130 is reduced due to extrusion. In this way, it is ensured that the thermal interface material 130 can be filled between the chip 110 and the integrated heat spreader 140.

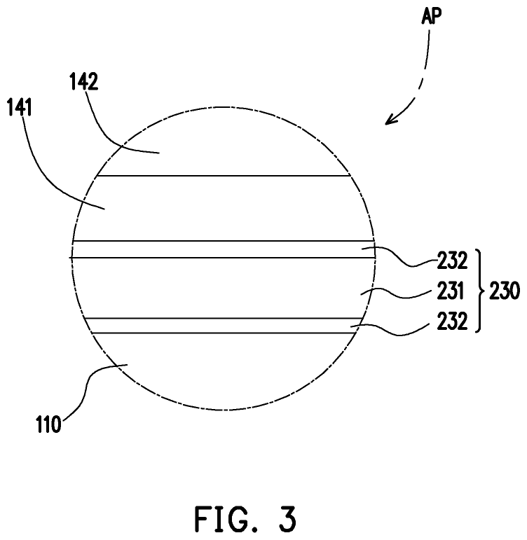

FIG. 3 is a partial cross-sectional view of a package structure according to another embodiment of the present invention. Referring to FIG. 3, it should be noted that, FIG. 3 is equivalent to the enlarged view of the partial AP in FIG. 1, which means that the rest of the components can still be the same as those shown in FIG. 1, and will not be repeated here. The difference from the foregoing is that, the thermal interface material 230 is used to replace the aforementioned thermal interface material 130 in the embodiment. Here, the thermal interface material 230 is an indium-based solder material, especially gold-based indium solder, including an indium layer 231 and gold layers 232 on opposite sides. It has high tensile strength and excellent thermal and electrical conductivity (heat transfer coefficient 81.8 W/m·K), and it is combined between the integrated heat spreader 140 and the chip 110 by soldering process. Furthermore, in order to increase the degree of bonding and bonding strength, the surface where the chip 110 is in contact with the solder material (that is, the thermal interface material 230) and the surface that the integrated heat spreader 140 is in contact with the solder material (that is, the thermal interface material 230) are formed by plating the gold layers 232 on the opposite surfaces of the indium layer 231, so as to serve as a structural buffer (using the malleability of the gold layers 232) when the expansion coefficient difference is too large.

It should be mentioned that, the aforementioned another thermal interface material 160 can also be the liquid metal shown in FIG. 1 or the solder material shown in FIG. 3.

In summary, in the above-mentioned embodiment of the present invention, the heat spreader of the embodiment is based on the graphite plate, and its outer surface is completely coated with copper layer to form the desired integrated heat spreader. Thereby, the heat generated by the chip can be effectively and quickly transferred to the heat spreader through the thermal interface material, and dissipated from the heat spreader accordingly.

Furthermore, in order to have a better configuration effect between the heat spreader and the surrounding stacked components, a nickel layer is plated on the outer surface of the copper layer to protect the copper layer from corrosion. In addition, the thermal interface material used to fill between the chip and the heat spreader can be selected from liquid metal and a solder material containing indium. When using the solder material, the heat spreader and the chip that are in contact with it must be plated with the gold layer to avoid cracking due to large differences in expansion coefficients, that is, the extensibility of the gold layer can buffer the situation where the aforementioned expansion coefficient difference is too large.

What is claimed is:

1. A packaging structure for a chip and an integrated heat spreader, comprising:
a substrate;
a chip, disposed on the substrate;
a thermal interface material, disposed on the chip; and
an integrated heat spreader, in a lid shape, disposed on the substrate to cover the chip and the thermal interface material, wherein the thermal interface material is abutted between the chip and the integrated heat spreader, the integrated heat spreader is composed of a graphite plate and at least one copper layer, wherein an exterior surface of the graphite plate is totally covered by the copper layer.

2. The packaging structure for the chip and the integrated heat spreader according to claim 1, wherein an exterior surface of the copper layer is plated with a nickel layer.

3. The packaging structure for the chip and the integrated heat spreader according to claim 2, the sum of the thicknesses of the copper layer and the nickel layer located on one of the surfaces of the graphite plate is 0.05 mm to 2 mm.

4. The packaging structure for the chip and the integrated heat spreader according to claim 1, wherein the thermal interface material is liquid metal with a heat transfer coefficient of 30-40 W/m·K.

5. The packaging structure for the chip and the integrated heat spreader according to claim 1, wherein the thermal interface material is a solder material containing indium, with a heat transfer coefficient of 81.8 W/m·K, which is combined between the integrated heat spreader and the chip by a soldering process.

6. The packaging structure for the chip and the integrated heat spreader according to claim 5, wherein the surface of the integrated heat spreader in contact with the solder material and the surface of the chip in contact with the solder material are respectively plated with a gold layer.

7. The packaging structure for the chip and the integrated heat spreader according to claim 1, wherein the thickness of the graphite plate is 0.7 mm to 3 mm.

8. The packaging structure for the chip and the integrated heat spreader according to claim 1, wherein the thickness of thermal interface material is 0.1 mm to 0.2 mm.

9. The packaging structure for the chip and the integrated heat spreader according to claim 1, wherein the chip is a bare die.

10. The packaging structure for the chip and the integrated heat spreader according to claim 1, wherein the integrated heat spreader further comprises a heat dissipation fin which is disposed on the integrated heat spreader and away from the chip and the thermal interface material.
